(19) United States
(12) Patent Application Publication
(10) Pub. No.: US 2026/0030393 A1
(43) Pub. Date: Jan. 29, 2026

(54) METHODS AND SYSTEMS FOR SCALABLE PHYSICS-BASED BATTERY PACK MODELING

(71) Applicant: JuliaHub, Inc., Boston, MA (US)

(72) Inventors: Christopher Rackauckas, Cambridge, MA (US); Marc Berliner, Boston, MA (US)

(21) Appl. No.: 19/274,782

(22) Filed: Jul. 21, 2025

Related U.S. Application Data
(60) Provisional application No. 63/674,411, filed on Jul. 23, 2024.

(51) Int. Cl. G06F 30/10

(52) U.S. Cl. CPC G06F 30/10

(57) ABSTRACT

A computer-implemented method for modeling thermal and electrochemical properties of lithium-ion battery packs is disclosed. A physics-based thermo-electro-chemical battery model is received comprising electrochemical reaction equations and thermal transport equations. A computer aided design (CAD) file is imported defining physical cell arrangements within a battery pack. Thermal connectivity matrices are automatically generated from the CAD file, where the matrices define heat transfer pathways between adjacent cells. A scaling algorithm transforms single-cell Single-Particle Model (SPM) equations into multi-cell coupled differential equations for the battery pack. The thermal and electrochemical behavior are simulated across the battery pack using the scaled equations to determine at least one battery performance characteristic based on the simulation.

### CROSS-REFERENCE TO RELATED APPLICATIONS

This application claims the benefit of U.S. Provisional Patent Application No. 63/674,411 filed Jul. 23, 2024 entitled “METHODS, DEVICES, AND SYSTEMS FOR THERMAL BATTERY MODELING”, the entire content of which is incorporated by reference herein.

### TECHNICAL FIELD

The field of the invention relates generally to battery modeling. More specifically, the field of the invention relates to methods and systems that integrate computer-aided design (CAD) files with accurate single-particle models (SPM) to simulate and predict performance characteristics across large-scale battery pack configurations.

### BACKGROUND

Cell-level thermo-electro-chemical modeling of lithium-ion batteries (Li-ion batteries) is a process that simulates the interplay between thermal, electrochemical, and mechanical behaviors and may be used for predicting the performance and lifespan of Li-ion batteries at both the cell and pack level.

One challenge of modeling lithium-ion batteries includes cell-to-cell variation that may result from manufacturing tolerances, thermal gradients, and aging disparities. These differences between cells can result in inaccurate modeling of batteries when scaled to the pack-level (e.g., multi-cell configurations exceeding 1,000 cells). Many current models employ “one-size-fits-all” approaches and, therefore, do not account for cell-to-cell variation, leading to prediction errors in real-world battery pack performance.

Moreover, current methods are often computationally inefficient (slow to simulate), difficult to solve robustly, and scale poorly to the pack level. For example, some models (e.g., Simscape Battery) may scale well but may have relatively inaccurate battery physics. Other models (e.g., COMSOL GT-AutoLion) may have accurate physics but do not scale well.

One scenario in which accurate thermo-electro-chemical modeling of lithium-ion batteries at the pack level is important is preventing thermal runaway. Thermal runaway in a battery pack is a failure mode in which an increase in temperature leads to a self-sustaining and uncontrollable reaction, causing the temperature to rise further. This process can result in heat, flames, and potentially explosive gases.

A thermal runaway typically starts with an initial overheating event, which could have contributing external factors such as high ambient temperatures, internal factors like overcharging, excessive discharging, or a short circuit within the battery cell. As the temperature increases, the battery's internal components, such as the electrolyte and electrode materials, start to degrade and react chemically. This degradation produces more heat.

Accurately predicting conditions for a thermal runaway scenario can prevent thermal runaway from occurring. Understanding and mitigating the risk of thermal runaway may be useful in applications like electric vehicles, portable electronics, and energy storage systems.

Accordingly, there is a need for improved methods, devices, and systems for thermal battery modeling that integrate computer-aided design files with scalable physics-based models to perform accurate multi-cell battery pack simulation while maintaining computational efficiency.

### SUMMARY

A computer-implemented method for modeling thermal and electrochemical properties of lithium-ion battery packs is disclosed herein where a physics-based thermo-electro-chemical battery model is received comprising electrochemical reaction equations and thermal transport equations. A computer aided design (CAD) file is imported defining physical cell arrangements within a battery pack. Thermal connectivity matrices are automatically generated from the CAD file, where the matrices define heat transfer pathways between adjacent cells. A scaling algorithm transforms single-cell Single-Particle Model (SPM) equations into multi-cell coupled differential equations for the battery pack. The thermal and electrochemical behavior are simulated across the battery pack using the scaled equations to determine at least one battery performance characteristic based on the simulation.

In certain embodiments, the battery performance characteristic is determined to comprise thermal runaway probability, remaining battery lifetime, cell-to-cell performance variations under different charge/discharge rates, or degradation patterns at end-of-life. Multiple physics-based thermo-electro-chemical battery models are supported, including Doyle-Fuller-Newman (DFN) model, Single-Particle Model (SPM), or SPM with electrolyte (SPMe).

The thermal connectivity matrices are generated through a systematic process wherein three-dimensional cell position coordinates are extracted from the CAD file, inter-cell distances and contact areas are calculated, thermal resistance values are determined based on cell casing materials and air gaps, and a sparse matrix representation of thermal coupling coefficients is constructed.

The scaling algorithm computationally decomposes the battery pack is into hierarchical thermal zones. Next, model order reduction techniques are applied to repeated cell structures, algebraic simplification of symbolic expressions is performed, and cell-specific compiled code segments are generated. In preferred embodiments, O(n) computational complexity is maintained for battery packs containing up to 10,000 cells, where n represents the number of cells.

For thermal runaway probability determination, temperature gradients exceeding 5° C. between adjacent cells may be monitored, exothermic reaction rates may be computed using Arrhenius kinetics when cell temperature exceeds 60° C., separator melting probability may be determined based on material-specific thermal thresholds, and Monte Carlo simulations may be executed to assess cascade failure propagation. A safety assessment report may also be generated identifying cells with thermal runaway probability exceeding a predetermined threshold.

Partial differential equations may be discretized using finite volume method (FVM), coupled thermo-electrochemical equations are solved with adaptive time stepping, and numerical stability is maintained through implicit integration schemes. Various battery pack configurations may be modeled, including hexagonal module configurations, square module configurations, cylindrical jelly-roll arrangements, prismatic arrangements, and pouch cell arrangements.

A non-transitory computer-readable storage medium is also disclosed, storing instructions that cause a computing system to perform the modeling operations. In certain embodiments, real-time thermal monitoring is implemented with update frequencies of at least 10 Hz during high-current discharge events. Compilation time is reduced by at least 100-fold compared to standard symbolic computation methods for battery packs exceeding 1,000 cells.

Cylindrical cell thermal dynamics may be modeled using radial heat equation solutions, where azimuthal and axial temperature variations are accounted for, and surface-to-core temperature differentials are coupled with ambient cooling conditions. When safety assessment reports are generated, visual heat maps are created showing temperature distributions across the battery pack, thermal hotspots with temperature deviations exceeding 10° C. from pack average are identified, cooling system modifications are recommended to mitigate identified risks, and time-to-failure estimates are provided for critical thermal scenarios.

Prediction accuracy within 0.5% error is achieved for battery state-of-charge and current under standard drive cycles. The thermal connectivity matrices are configured to incorporate conductive heat transfer through cell casings and interconnects, convective heat transfer coefficients for air or liquid cooling systems, radiative heat transfer between non-adjacent cells, and phase change material thermal buffers when present.

Simulation results are validated against experimental thermal data, model parameters are adjusted based on cell-to-cell manufacturing variations, adaptive mesh refinement is implemented for regions approaching critical thermal conditions, and simulation time steps are dynamically adjusted based on temperature rate-of-change. Machine learning models trained on historical battery operational data are utilized to enhance prediction accuracy for remaining lifetime and degradation patterns.

The disclosed methods and systems enable efficient computational modeling of large-scale battery packs while maintaining high-fidelity physics-based accuracy, providing for battery safety assessment, lifetime prediction, and performance optimization in electric vehicle and energy storage applications.

The features and advantages described in this summary and the following detailed description are not all-inclusive. Many additional features and advantages will be apparent to one of ordinary skill in the art in view of the drawings, specification, and claims presented herein.

### BRIEF DESCRIPTION OF THE DRAWINGS

The present embodiments are illustrated by way of example and are not intended to be limited by the figures of the accompanying drawings. In the drawings:

FIG. 1 depicts a graph illustrating a single particle model of a battery cell for an example case study for battery modeling surrogates in accordance with embodiments of the present disclosure.

FIG. 2 depicts an exemplary schematic of the DFN model for an LiC₆/LCO cell during discharge in accordance with embodiments of the present disclosure.

FIG. 3 depicts a diagram illustrating an example hexagonal module configuration in accordance with embodiments of the present disclosure.

FIG. 4 depicts a diagram illustrating an example square module configuration in accordance with embodiments of the present disclosure.

FIG. 5 depicts a graph illustrating compilation time differences between a standard complier and a compiler of the present disclosure as a function of the number of cells in a pack accordance with embodiments of the present disclosure.

FIG. 6 depicts a system architecture block diagram illustrating functional components for implementing the disclosed methods.

FIG. 7 depicts a flow chart illustrating a method for thermal battery modeling in accordance with embodiments of the present disclosure.

FIG. 8 depicts graphs illustrating current and battery capacity as a function of time for an example case study for battery modeling surrogates in accordance with embodiments of the present disclosure.

### DETAILED DESCRIPTION

As mentioned, scaling multiphysics thermo-electro-chemical cell models to pack-level thermal models presents challenges due to the interplay of physical phenomena at different scales. At the cell level, models should accurately capture detailed electrochemical reactions and thermal effects. When extending these models to the pack level, however, the design space becomes enormous due to the number of different cell geometries (cylindrical, pouch, etc.), different configurations of the cells (including the number of cells in series/parallel), and modeling of complicated thermal environments (such as air or liquid cooling).

Conventional methods and systems focus on the efficient modeling of battery packs under different design configurations. For example, pack-level thermal models are commonly modeled using the finite element method (FEM) or computational fluid dynamics (CFD).

The challenge in incorporating pack thermals with the cell models is generalizing the approach for a wide variety of module and pack configurations. To do so, many companies optimize or tweak the design of their modules. However, it is insufficient to simply hard-code a few example configurations that are minimally customizable. The present disclosure addresses these challenges and limitations, as discussed in greater detail below.

In contrast to current methods and systems, the methods and systems described herein can make accurate and timely predictions of thermal runaway so that they can be avoided. This may include modeling or simulating different separator geometries, battery chemistry, casing material, multi-cell pack configuration or arrangement, weight, number of cells are in there, battery size etc. Using accurate physics-based thermo-electro-chemical cell models scaled to the pack-level allows the present disclosure to determine and ensure that a given battery configuration is safe from thermal runaway, at least to a high statistical probability. The present disclosure may allow for importing and exporting of custom CAD models that interface directly with the thermo-electro-chemical battery models (e.g., from JuliaSimBatteries.jl) in a way that keeps the compilation time manageable.

In brief, the subject matter described herein uses one or more physics-based electrochemical models to model the thermal properties of lithium-ion batteries. Some example physics-based electrochemical models include: Doyle-Fuller-Newman (DFN), Single-Particle Model (SPM), and SPM with electrolyte (SPMe). Partial differential equations (PDEs) are discretized with Finite Volume (FVM). The result is a model that is one hundred times faster than conventional models such as Python Battery Mathematical Modelling/.mat format (PyBaMM/MAT) using a tool for nonlinear optimization and algorithmic differentiation (AD) such as CasADi.

Additionally, the subject matter described herein includes thermal and degradation submodels, as well as models for modelling cells, modules, and packs. Using parameters for NMC, NCA, LFP, and LCO, the user can define their own chemistries. For example, the present subject matter provides for estimating the remaining lifetime of a battery with 99% confidence and can directly consider complex charge/discharge protocols. This can also include accurate modeling of electric vehicle drive cycles by predicting battery demand from an electric vehicle in seconds with less than 0.5% error.

In some embodiments, machine learning tools can be used to improve capacity fade degradation models (which express voltage changes as a function of time or charge/discharge cycles) by degrading a battery 150,000 times faster than real-time.

Another advantage of the present disclosure is the ability to answer questions about battery degradation. For example, determining why different C-rates cause different distributions for cells with major differences or determining what causes variation at end of life (EOL) may be done using JuliaSim battery pack models.

These advantages allow the user to simulate and predict worst-case scenarios for battery packs, such as internal shorting leading to thermal runaway and propagation within the pack, by using advanced fault scenarios with thermo-electro-chemical models.

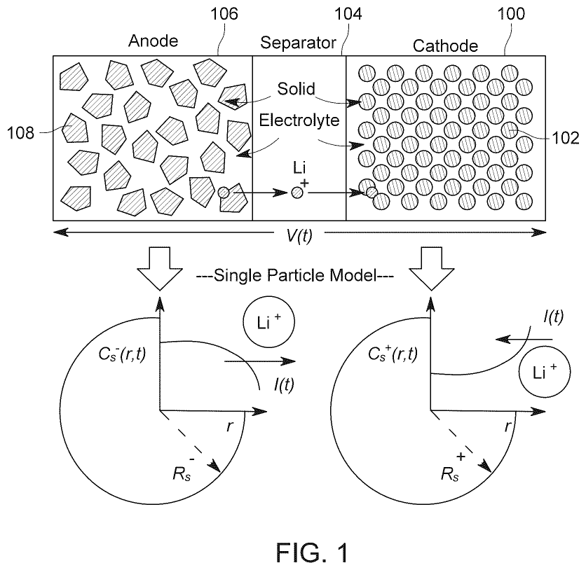

FIG. 1 depicts a schematic representation of the Single-Particle Model (SPM) implementation for lithium-ion battery cells as utilized in the disclosed scaling algorithm for multi-cell battery pack configurations. The illustration demonstrates the fundamental electrochemical structure underlying the physics-based thermo-electro-chemical modeling system, showing the cathode electrode 100 comprising lithium cobalt oxide (LiCoO2) particles 102, the separator membrane 104, and the anode electrode 106 comprising lithium carbon (LiC6) particles 108. The voltage input V(t) drives lithium ion transport between the electrodes, with the disclosed SPM equations capturing the electrochemical reaction dynamics within each electrode structure.

The Single-Particle Model representations for both cathode and anode electrodes illustrate the radial diffusion processes captured by the disclosed scaling algorithm when transforming single-cell SPM equations into multi-cell coupled differential equations. Each electrode's SPM accounts for lithium concentration gradients within the solid particles, with current I(t) profiles reflecting the electrochemical reaction rates computed through the physics-based modeling system. The spherical particle geometry shown for both electrodes represents the fundamental mathematical framework upon which the disclosed thermal connectivity matrices operate when coupling multiple cells within complex battery pack configurations.

The electrochemical foundation illustrated in FIG. 1 provides the basis for the disclosed CAD-integrated modeling system's capability to simulate thermal and electrochemical behavior across large-scale battery pack arrangements. The SPM equations depicted serve as the core computational elements that undergo algebraic simplification and symbolic expression processing through the disclosed scaling algorithm, enabling the generation of cell-specific compiled code segments for parallel execution. The fundamental electrochemical processes shown support the disclosed thermal runaway probability assessment methods through computation of exothermic reaction rates and separator melting probability determination based on the underlying electrochemical reaction dynamics captured within the SPM framework.

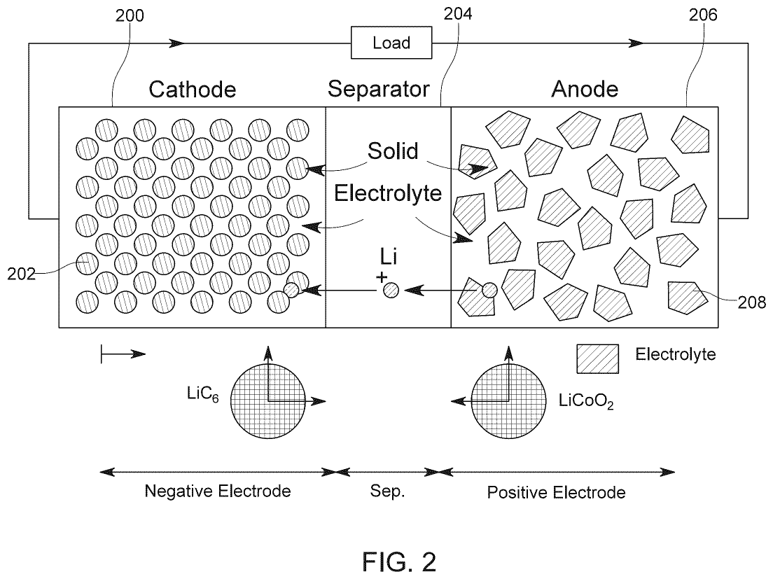

FIG. 2 depicts an exemplary schematic of the DFN model for an LiC₆/LCO cell during discharge and is showing the cathode electrode 200 comprising lithium cobalt oxide (LiCoO2) particles 202, the separator membrane 204, and the anode electrode 106 comprising lithium carbon (LiC6) particles 208. The voltage input V(t) drives lithium ion transport between the electrodes, with the disclosed SPM equations capturing the electrochemical reaction dynamics within each electrode structure.

Regarding cell-level thermals, the JuliaSimBatteries.jlmodels include 1-D thermal physics along the x-direction of a cell. The partial differential equations (PDEs) take the form below:

$${ρ}_{i} {C}_{p , i} \frac{\partial T ( x , t )}{\partial t} = \frac{\partial }{\partial x} ( {λ}_{i} \frac{\partial T ( x , t )}{\partial x} ) + {Q}_{t o t} ( x , t ) \qquad Equation 1$$

where ρ is density, Cₚ is specific heat capacity, T is temperature, λ is thermal conductivity, Qₜₒₜ is the aggregate internal heat generation inside the cell, and the subscript i refers to the section of the cell, beginning at x=0 and ending at x=L:
nce—negative current collector
ne—negative electrode
s—separator
pe—positive electrode
pcc—positive current collector

While the thermal PDE model in Equation 1 is accurate for the internals of the cell, it fails to capture (a) the (often significant) difference between the core and surface temperature of the cell, (b) the casing and its material properties, and (c) the geometric arrangement of the cell, commonly a cylindrical (“jelly roll”), prismatic, or pouch cell. To accurately simulate pack-level heating/cooling, more detailed thermal models can eliminate the shortcomings of current 1-D thermal models. Cylindrical geometries are the most popular for lithium-ion batteries and are the focus of the extended thermal model in this document.

While the 1-D thermal PDEs (1) consider spatial variation of temperature, the temperature gradients are often dwarfed in magnitude compared to the internal heat generation Qₜₒₜ, even for extreme operating conditions. As such, we may consider an x-averaged internal cell temperature and heat generation,

$${T}_{c} ( T ) = \frac{{\int }_{0}^{L} T ( {x}^{′} , t ) {dx}^{′}}{{\int }_{0}^{L} dx} \qquad Equation 2$$

$${Q}_{c} ( t ) = \frac{{\int }_{0}^{L} {Q}_{tot} ( {x}^{′} , t ) {dx}^{′}}{{\int }_{0}^{L} dx} \qquad Equation 3$$

Regarding core and surface temperature dynamics, it may be appreciated that the above thermal model only considers the internal cell temperature. However, in practice (both in a lab setting and in application) the internal cell temperature is not measurable and only the surface temperature of the cell is measurable. One thermal model solves for both the internal and the surface temperature of the cell by making a low-order approximation of the temperature in the radial-direction r∈[0, Rs] cylindrical cell PDE by considering two new equations,

$${C}_{c} \frac{d {T}_{c}}{d t} = \frac{{T}_{s} ( t ) - {T}_{c} ( t )}{{R}_{c}} + {Q}_{c} ( t ) \qquad Equation 4$$

$${C}_{s} \frac{d {T}_{s}}{d t} = \frac{{T}_{a m b} ( t ) - {T}_{s} ( t )}{{R}_{u}} - \frac{{T}_{s} ( t ) - {T}_{c} ( t )}{{R}_{c}} \qquad Equation 5$$

where subscript c refers to the “core” of the cell (r=0) and s is the “surface” (r=R), T_{amb}(t) is the ambient temperature, Rc is the heat conduction resistance, Ru is the convection resistance, Cc is the core heat capacity, and Cs is the surface heat capacity. The thermal model contains values for these parameters, which will likely not substantially change from one cell to the next. While neglecting the azimuth and axial coordinates is appropriate for a cell in a constant-temperature ambient environment, this assumption may break down in a pack or module that experiences significant convection and temperature gradients at the surface of the cell. In this case, more detailed spatial information may be required to accurately model the multiphysics system.

Next, solving the cylindrical cell casing thermal PDEs is described. While the thermal model described above with respect to Equations 4 and 5 adds an additional level of detail to the simulation, the present disclosure takes this further by coupling the PDE of the radial-direction cylindrical heat equation to the core and surface model,

$$ρ {C}_{p} \frac{\partial T ( r , t )}{\partial t} = \frac{1}{r} \frac{\partial }{\partial r} ( rk \frac{\partial T ( r , t )}{\partial r} ) \qquad Equation 6$$

with boundary conditions

$${T ( r , t ) \vert}_{r = 0} = {T}_{c} ( t ) \qquad Equation 7$$

$${T ( r , t ) \vert}_{r = R} = {T}_{s} ( t ) \qquad Equation 8$$

This system may have an analytical or series solution for T(r, t) given constant ρ, Cₚ, k and arbitrary time-dependent boundary conditions. If it does have an analytical solution, we can treat it as an observable (in the ModelingToolkitsense), such that it does not contribute to the computational complexity of solving the problem. Otherwise, this system can be solved with a finite difference method (FDM) or with spectral methods that work appropriately with arbitrary time-dependent boundary conditions. The finite volume method (FVM) may be inappropriate for this application because of the Dirichlet boundary conditions described in Equations 7 and 8, which can only be enforced in the weak form.

Regarding pack-level/module-level thermals, it may be appreciated that scaling multiphysics thermo-electro-chemical cell models to pack-level thermal models presents significant challenges due to the complex interplay of physical phenomena at different scales. At the cell level, models should accurately capture detailed electrochemical reactions and thermal effects. When extending these models to the pack level, the design space becomes enormous as we consider different cell geometries (cylindrical, pouch, etc.), configurations of the cells including the number of cells in series/parallel, and modeling of complicated thermal environments, such as air or liquid cooling.

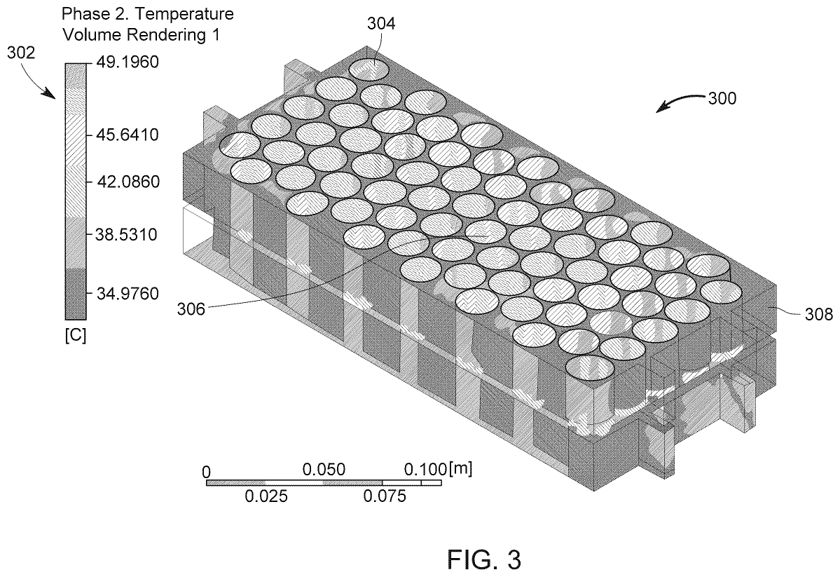

FIG. 3 depicts a thermal simulation visualization of an exemplary hexagonal module configuration demonstrating the thermal connectivity matrix generation and heat transfer pathway modeling in accordance with embodiments of the present disclosure. The hexagonal battery pack arrangement shows thermal distribution analysis with temperature gradients ranging from approximately 32.0° C. to 45.64° C. across the cell configuration, as computed using the disclosed CAD-integrated physics-based modeling system. The thermal visualization demonstrates inter-cell heat transfer pathways automatically generated from CAD file coordinates, wherein thermal resistance values between adjacent cells are calculated based on cell casing materials and air gaps.

The tightly packed multi-cell configuration 300 illustrated in FIG. 3 presents geometric relationships that often require sophisticated CAD file processing to accurately capture inter-cell thermal coupling. Adjacent cells exhibit varying temperature distributions due to differential heat generation, thermal conduction through cell casings, and convective cooling effects at different positions within the pack. Shown here, cell 304 is located at an outer edge of the multi-cell block 308 while cell 306 is located at the center. Notably, cell 304 has a lower temperature than cell 306 that may result from their relative locations to other cells. The disclosed thermal connectivity matrices automatically capture these inter-cell relationships by extracting three-dimensional cell position coordinates from the CAD file and calculating thermal coupling coefficients based on proximity, contact area, and material properties.

The hexagonal module configuration provides optimal packing density while enabling accurate thermal connectivity matrix construction for multi-cell coupled differential equations. The temperature variations visible across the pack illustrate the thermal interdependencies captured by the disclosed scaling algorithm that transforms single-cell Single-Particle Model equations into multi-cell coupled differential equations. The color-coded temperature distribution illustrates the system's capability to predict thermal hotspots and temperature variations across large-scale battery pack configurations, supporting thermal runaway probability assessment and performance characteristic determination as disclosed in the claimed methods.

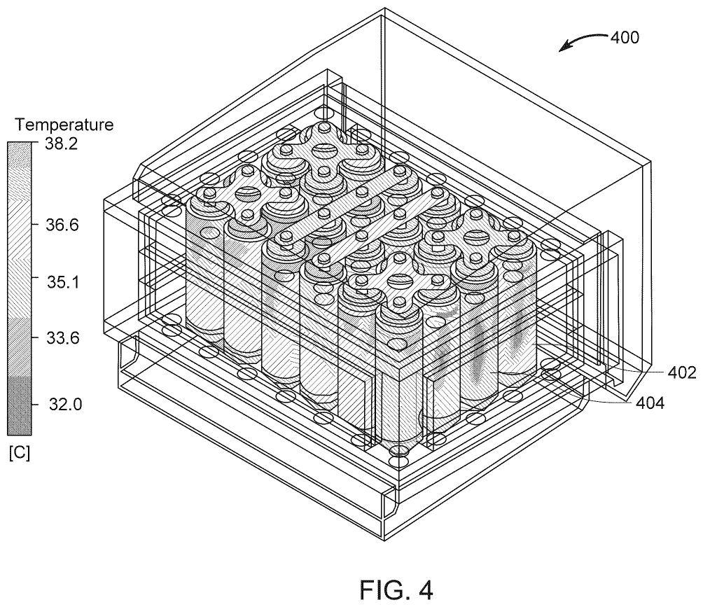

FIG. 4 depicts a thermal simulation visualization of an exemplary square module configuration 400 comprising cylindrical battery cells, such as adjacent cells 402 and 404, arranged in a rectangular grid pattern, representing a typical commercial battery pack architecture commonly deployed in electric vehicle and energy storage applications. The thermal distribution analysis shows temperature gradients ranging from approximately 32.0° C. to 38.2° C. across the cylindrical cell arrangement, illustrating the complex temperature variations and thermal dynamics inherent in such tightly packed multi-cell configurations. The visualization demonstrates the disclosed CAD-integrated thermal modeling system's capability to process the intricate geometric relationships and thermal interdependencies present in standard commercial battery pack designs.

The square module configuration illustrated in FIG. 4 shows thermal complexity arising from the close proximity of cylindrical cells within the rectangular grid arrangement. Each cell position experiences distinct thermal conditions based on its location within the pack, proximity to neighboring cells, and access to cooling pathways, resulting in heterogeneous temperature distributions across the configuration. The thermal coupling between adjacent cells creates complex heat transfer dynamics that vary throughout the pack geometry, requiring modeling of conductive heat transfer through cell casings, convective heat transfer coefficients for air gaps, and radiative heat transfer between cells at different positions.

The disclosed thermal connectivity matrices automatically process the CAD file data to extract three-dimensional cell position coordinates and generate thermal coupling coefficients that capture the complex inter-cell relationships inherent in this typical battery pack configuration. The scaling algorithm transforms single-cell Single-Particle Model equations into multi-cell coupled differential equations specifically adapted to the geometric and thermal characteristics of the square module arrangement. The thermal simulation results enable accurate prediction of temperature variations, thermal hotspot identification, and thermal runaway probability assessment across the entire pack configuration through the disclosed physics-based modeling approach that accommodates the full complexity of commercial battery pack designs.

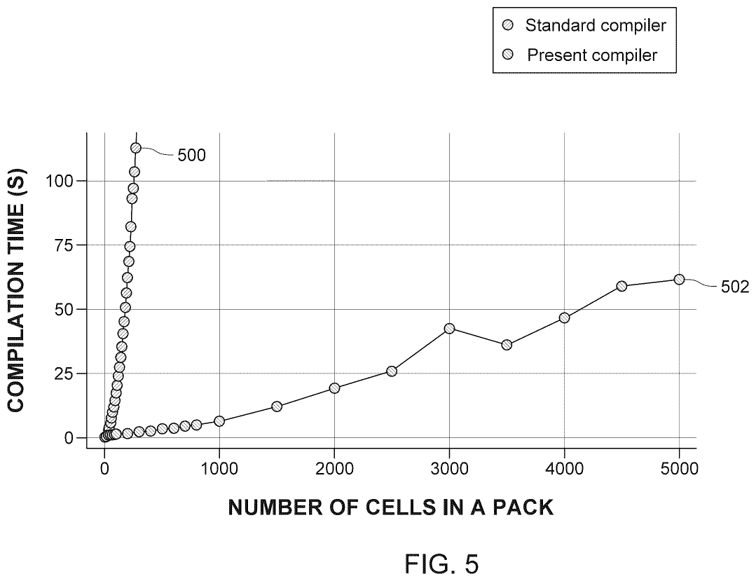

FIG. 5 depicts a performance analysis graph illustrating the computational efficiency characteristics of the disclosed scaling algorithm as applied to increasing battery pack cell configurations in accordance with embodiments of the present disclosure. The graph demonstrates the compilation time performance of the disclosed compiler system across battery pack configurations ranging from small cell counts to multi-thousand-cell arrangements, specifically illustrating the maintenance of linear computational complexity O(n) for battery packs containing up to 10,000 cells as claimed in the disclosed methods. Here, standard compiler time 500 grows quickly (e.g., exponentially) as the number of cells in a pack increases, while using the methods disclosed herein result in a compiler time 502 that grows substantially linearly with the number of cells in a pack.

The disclosed compilation system exhibits substantially controlled compilation time scaling characteristics, maintaining compilation times within a manageable range of 0-100 seconds across the entire spectrum of battery pack configurations tested. The performance curve illustrates the practical implementation of the disclosed scaling algorithm that transforms single-cell Single-Particle Model equations into multi-cell coupled differential equations while preserving computational efficiency through hierarchical thermal zone decomposition, model order reduction techniques applied to repeated cell structures, and algebraic simplification of symbolic expressions.

The compilation time performance data shows that the disclosed system can process large-scale battery pack configurations containing thousands of cells while maintaining practical operational efficiency for commercial battery modeling applications. The graph validates the disclosed cell-specific compiled code generation for parallel execution, enabling real-time thermal monitoring with update frequencies of at least 10 Hz during high-current discharge events. The performance characteristics illustrated demonstrate the practical scalability of the disclosed CAD-integrated physics-based modeling system for complex multi-cell battery pack configurations requiring comprehensive thermal connectivity matrix generation and thermal runaway probability assessment across extensive cell arrays.

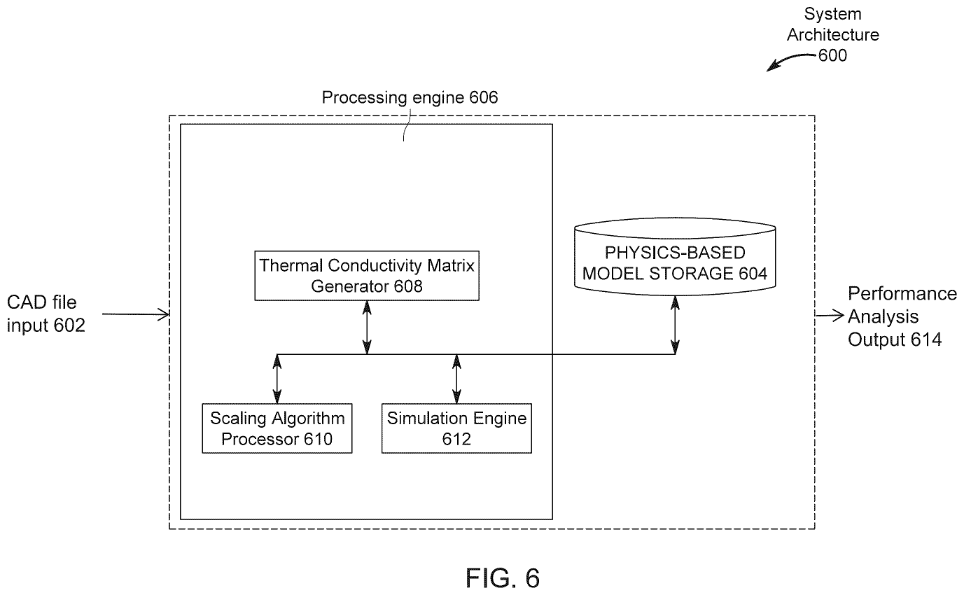

FIG. 6 depicts a functional block diagram illustrating system architecture 600 for implementing the disclosed scalable physics-based thermo-electro-chemical battery pack modeling methods comprising software modules executed on a computing system in accordance with embodiments of the present disclosure. The system architecture 600 receives CAD file input 602 comprising computer aided design files defining physical cell arrangements within battery pack configurations, including three-dimensional cell position coordinates, geometric specifications, and material property definitions for processing through the disclosed modeling framework.

The system architecture 600 further comprises physics-based model storage 604 containing thermo-electro-chemical battery models including electrochemical reaction equations and thermal transport equations, supporting multiple model implementations including Doyle-Fuller-Newman (DFN) model, Single-Particle Model (SPM), and SPM with electrolyte (SPMe). The physics-based model storage 604 provides foundational mathematical frameworks and parameter sets for NMC, NCA, LFP, and LCO battery chemistries utilized throughout the modeling process.

The system architecture 600 includes processing engine 606 comprising integrated software modules that execute the disclosed CAD-integrated modeling methods through coordinated computational operations. The processing engine 606 comprises thermal connectivity matrix generator 608 that automatically processes CAD file input 602 to extract three-dimensional cell position coordinates, calculate inter-cell distances and contact areas, determine thermal resistance values based on cell casing materials and air gaps, and construct sparse matrix representations of thermal coupling coefficients defining heat transfer pathways between adjacent cells.

The processing engine 606 further comprises scaling algorithm processor 610 that transforms single-cell Single-Particle Model equations from physics-based model storage 604 into multi-cell coupled differential equations for battery pack configurations through hierarchical thermal zone decomposition, model order reduction techniques applied to repeated cell structures, algebraic simplification of symbolic expressions, and generation of cell-specific compiled code segments for parallel execution while maintaining O(n) computational complexity for battery packs containing up to 10,000 cells.

The processing engine 606 includes simulation engine 612 that executes thermal and electrochemical behavior simulation across battery pack configurations using scaled equations from scaling algorithm processor 610 and thermal connectivity matrices from matrix generator 608, discretizing partial differential equations using finite volume method, solving coupled thermo-electrochemical equations with adaptive time stepping, and maintaining numerical stability through implicit integration schemes. The system architecture 600 generates performance analysis output 614 comprising battery performance characteristics including thermal runaway probability, remaining battery lifetime, cell-to-cell performance variations under different charge and discharge rates, and degradation patterns at end-of-life, with safety assessment reporting including identification of cells with thermal runaway probability exceeding predetermined thresholds.

The disclosed system may include a graphical user interface for configuring and executing physics-based thermo-electro-chemical battery pack modeling operations. The interface provides integrated access to the disclosed CAD file importation and thermal connectivity matrix generation capabilities through structured input and analysis sections. An experiments configuration section enables specification of initial battery charge states and operational planning parameters, including charge duration protocols such as fifteen-minute charging cycles, which interface directly with the Single-Particle Model scaling algorithms to generate multi-cell coupled differential equations for specified battery pack configurations.

The system may include analysis capabilities that provide comprehensive visualization and control for the disclosed thermal and electrochemical simulation processes. Cycle view functionality enables real-time monitoring of battery performance characteristics as computed through the physics-based thermo-electro-chemical modeling system, while plotting configuration options facilitate examination of specific performance metrics including thermal runaway probability, remaining battery lifetime, and cell-to-cell performance variations under different charge and discharge rates. Interactive parameter adjustment capabilities enable dynamic configuration of simulation parameters to accommodate various operational scenarios and testing protocols.

The disclosed system provides real-time visualization of simulation outputs generated through the scaling algorithm and thermal connectivity matrix calculations. The implementation facilitates comprehensive analysis of battery pack configurations imported through CAD files, enabling users to assess thermal hotspot development, temperature gradient monitoring, and performance characteristic determination across large-scale battery pack configurations. The integrated computational environment supports the disclosed safety assessment reporting capabilities, including identification of cells with thermal runaway probability exceeding predetermined thresholds and time-to-failure estimates for critical thermal scenarios as computed through the physics-based modeling system.

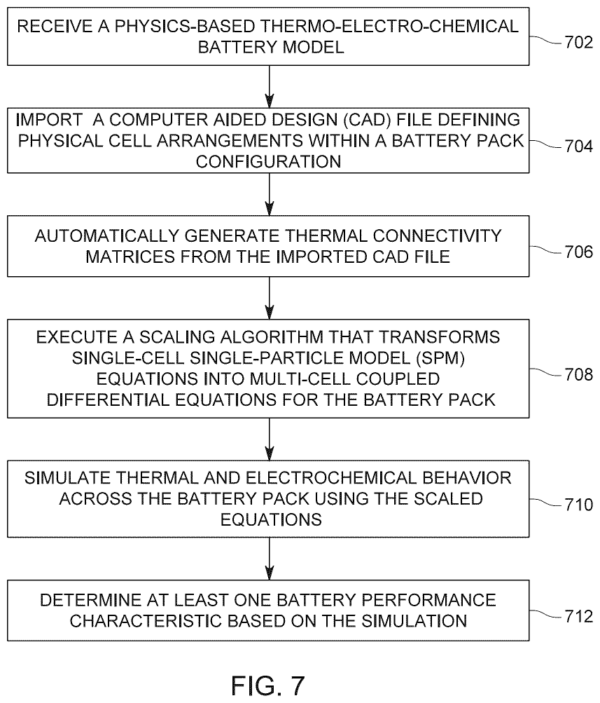

FIG. 7 depicts a comprehensive flow chart illustrating the computer-implemented method for modeling thermal and electrochemical properties of lithium-ion battery packs in accordance with embodiments of the present disclosure. The method provides systematic integration of computer-aided design files with physics-based thermo-electro-chemical modeling to enable accurate simulation and performance characteristic determination for large-scale battery pack configurations.

At step 702, the method includes receiving, by a processor, a physics-based thermo-electro-chemical battery model including electrochemical reaction equations and thermal transport equations. The physics-based battery model encompasses multiple supported implementations including Doyle-Fuller-Newman (DFN) model, Single-Particle Model (SPM), or SPM with electrolyte (SPMe). For example, the SPM implementation may include lithium diffusion equations for both anode and cathode materials, with parameter sets configured for lithium cobalt oxide (LiCoO2) cathode and lithium carbon (LiC6) anode chemistries, including diffusion coefficients, reaction rate constants, and thermal conductivity values.

At step 704, the method includes importing a computer aided design (CAD) file defining physical cell arrangements within a battery pack configuration. The CAD file import process accommodates multiple battery pack configurations including hexagonal module configurations, square module configurations, cylindrical jelly-roll arrangements, prismatic arrangements, and pouch cell arrangements. For example, a CAD file may specify a hexagonal battery pack containing 2,500 cylindrical cells arranged in a close-packed configuration, with each cell having 18650 form factor specifications including 18 mm diameter, 65 mm length, and defined spacing parameters between adjacent cells.

At step 706, the method includes automatically generating thermal connectivity matrices from the imported CAD file, where the matrices define heat transfer pathways between adjacent cells through mathematical representation of thermal coupling relationships. The thermal connectivity matrices mathematically capture heat transfer pathways by representing thermal coupling coefficients as sparse matrix elements, where each matrix element Tᵢⱼ represents the thermal conductance between cell i and cell j, calculated as the inverse of thermal resistance based on conductive, convective, and radiative heat transfer mechanisms. Step 706 may generate these matrices through execution of one or more various substeps described below.

A substep of the thermal connectivity matrix generation process in step 706 may include extracting three-dimensional cell position coordinates from the CAD file. For example, the system extracts Cartesian coordinates (x, y, z) for each cell center location within the battery pack, such as cell positions at coordinates (15.2 mm, 22.8 mm, 0 mm) for a cell in the first layer of a hexagonal arrangement.

Another substep of step 706 may include calculating inter-cell distances and contact areas between adjacent cells. For example, the system calculates the distance between two adjacent 18650 cylindrical cells as 19.5 mm center-to-center spacing, resulting in a 1.5 mm air gap, and determines the effective heat transfer contact area as 1,170 mm² based on the cylindrical geometry and proximity.

Another substep of step 706 may include determining thermal resistance values based on cell casing materials and air gaps between cells. For example, the system calculates thermal resistance through aluminum cell casings as 0.015 K/W based on material thermal conductivity of 205 W/m·K and geometric parameters, while air gap thermal resistance is calculated as 2.8 K/W based on natural convection coefficients and gap dimensions.

Another substep of step 706 may include constructing sparse matrix representation of thermal coupling coefficients. For example, the system generates a 2,500×2,500 sparse matrix for a 2,500-cell battery pack, where non-zero elements represent thermal coupling coefficients between adjacent cells, with typical values ranging from 0.05 W/K to 0.8 W/K depending on cell proximity and contact area.

At step 708, the method includes executing a scaling algorithm that transforms single-cell Single-Particle Model equations into multi-cell coupled differential equations for the battery pack configuration. The scaling algorithm execution integrates thermal connectivity matrices with electrochemical equations to create comprehensive multi-cell simulation framework. Step 708 achieves this transformation through coordinated execution of various substeps described below.

A substep of the scaling algorithm in step 708 may include decomposing the battery pack into hierarchical thermal zones for computational efficiency. For example, a 2,500-cell hexagonal battery pack may be decomposed into 25 thermal zones of 100 cells each, with each zone having defined thermal boundary conditions and inter-zone heat transfer coefficients.

Another substep of the scaling algorithm may also include applying model order reduction techniques to repeated cell structures to minimize computational complexity. For example, cells with identical geometric positions relative to their neighbors may utilize shared computational kernels, reducing the total number of unique differential equation sets from 2,500 to 150 for a battery pack with repeated structural patterns.

Another substep of the scaling algorithm may also include performing algebraic simplification of symbolic expressions to optimize computational performance. For example, common thermal diffusion terms appearing across multiple cell equations may be factored into shared computational elements, reducing floating-point operations by approximately 40% through symbolic manipulation techniques.

Another substep of the scaling algorithm may also include generating cell-specific compiled code segments for parallel execution across multiple processor cores. For example, the system generates optimized code segments that enable simultaneous solution of differential equations for up to 100 cells per processor core, utilizing vectorized mathematical operations and shared memory access patterns.

At step 710, the method includes simulating thermal and electrochemical behavior across the battery pack using the scaled equations from the scaling algorithm execution. This simulation process achieves substantially enhanced computational efficiency while maintaining superior accuracy compared to conventional battery modeling techniques, enabling real-time analysis of large-scale battery pack configurations that would be computationally prohibitive using traditional approaches. Step 710 may implement this efficient simulation through various substeps described below.

At one substep, the simulation may include discretizing partial differential equations using finite volume method to ensure numerical accuracy and stability. For example, the radial diffusion equation within each SPM particle is discretized into 10 finite volume elements, providing sufficient spatial resolution to capture lithium concentration gradients while maintaining computational efficiency.

At another substep, the simulation may include solving coupled thermo-electrochemical equations with adaptive time stepping to optimize computational performance. For example, the system dynamically adjusts time steps from 0.1 seconds during steady-state operation to 0.001 seconds during rapid transient events such as high-current discharge operations.

At another substep, the simulation may include maintaining numerical stability through implicit integration schemes that prevent computational divergence. For example, the system utilizes backward Euler integration methods for thermal equations and Crank-Nicolson schemes for electrochemical equations to ensure stable solution convergence across the entire simulation duration.

At step 712, the method may include determining at least one battery performance characteristic based on the simulation results. The performance characteristic determination process may generates multiple possible analytical outputs depending on the specific application requirements and operational scenarios under investigation.

In one embodiment, the determined battery performance characteristic may include thermal runaway probability assessment through monitoring temperature gradients exceeding 5° C. between adjacent cells, computing exothermic reaction rates using Arrhenius kinetics when cell temperature exceeds 60° C., determining separator melting probability based on material-specific thermal thresholds, and executing Monte Carlo simulations to assess cascade failure propagation across the battery pack configuration.

In another embodiment, the battery performance characteristic determined may include remaining battery lifetime calculation through analysis of capacity fade patterns, electrode degradation mechanisms, and electrolyte decomposition rates as computed through the integrated physics-based modeling framework over extended operational cycles, providing statistical confidence intervals for lifetime prediction accuracy.

In a further embodiment, the determined battery performance characteristic may include cell-to-cell performance variation analysis under different charge and discharge rates by comparing electrochemical behavior across individual cells within the battery pack under various operational protocols including fast charging scenarios and high-power discharge events, quantifying performance heterogeneity across the pack configuration.

In yet another embodiment, the determined battery performance characteristic may include degradation pattern identification at end-of-life conditions through comprehensive analysis of capacity loss, internal resistance increase, and thermal behavior changes as battery cells approach specified performance thresholds, enabling predictive maintenance scheduling and replacement planning.

The method generates comprehensive safety assessment reports identifying cells with thermal runaway probability exceeding predetermined thresholds and provides time-to-failure estimates for critical thermal scenarios through the integrated physics-based modeling framework. The performance characteristic determination enables optimization of battery pack configurations for enhanced safety, operational efficiency, and service lifetime across diverse commercial applications including electric vehicle powertrains and grid-scale energy storage systems.

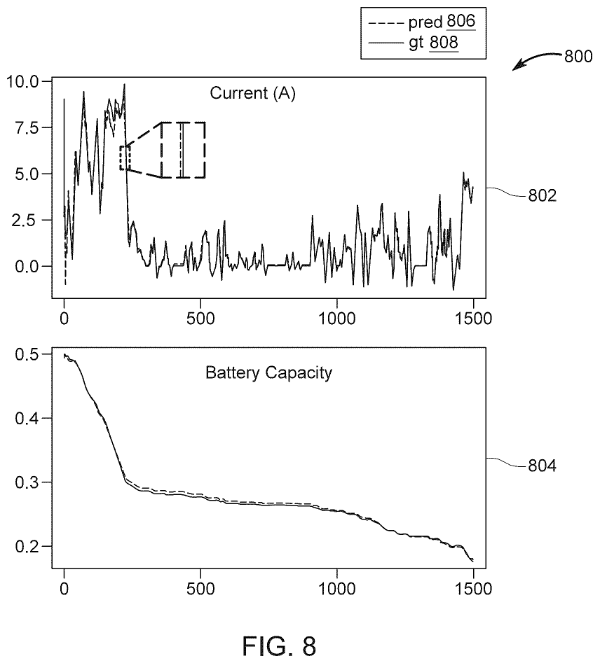

FIG. 8 depicts validation graphs illustrating current and battery capacity predictions generated through the disclosed physics-based thermo-electro-chemical modeling system as a function of time for an exemplary case study implementation. The graphical analysis demonstrates the accuracy of the disclosed CAD-integrated Single-Particle Model scaling algorithm in predicting real-world battery performance characteristics, with the current prediction curves showing precise correlation with observed battery current behavior throughout the operational cycle. The battery capacity prediction validation illustrates the disclosed system's capability to achieve prediction accuracy within 0.5% error for battery state-of-charge and current under standard drive cycles as claimed in the disclosed methods.

The temporal analysis presented in FIG. 8 validates the effectiveness of the disclosed thermal connectivity matrix calculations and multi-cell coupled differential equation solutions in capturing actual battery pack behavior. The current and capacity prediction curves demonstrate the practical implementation of the disclosed scaling algorithm that transforms single-cell Single-Particle Model equations into comprehensive multi-cell simulations while maintaining computational accuracy across complex battery pack configurations. The validation data supports the claimed capability to simulate thermal and electrochemical behavior across large-scale battery pack arrangements through the disclosed CAD file integration and physics-based modeling approach.

The prediction accuracy illustrated in FIG. 8 validates the disclosed machine learning model integration that utilizes historical battery operational data to enhance prediction accuracy for remaining lifetime and degradation patterns. The temporal correlation between predicted and observed performance characteristics demonstrates the robust computational foundation supporting the claimed thermal runaway probability assessment and performance optimization capabilities. The validation results confirm the disclosed system's capability to provide reliable battery performance predictions for electric vehicle drive cycle analysis and energy storage system optimization through the comprehensive physics-based thermo-electro-chemical modeling framework integrated with CAD-derived battery pack configurations.

Additionally, phase space analysis illustrates that the disclosed physics-based thermo-electro-chemical modeling system can generate comprehensive battery performance characteristic predictions through SPM scaling algorithm implementation. The phase space representation demonstrates the relationship between total battery current and total state of charge as computed through the disclosed multi-cell coupled differential equations, providing validation of the claimed prediction accuracy within 0.5% error for battery state-of-charge and current under standard drive cycles.

Phase space methodology illustrates the mathematical framework underlying the disclosed thermal connectivity matrix calculations and their integration with electrochemical modeling components. The phase space trajectory represents the dynamic behavior captured by the disclosed scaling algorithm as it transforms single-cell Single-Particle Model equations into multi-cell coupled differential equations that account for thermal interdependencies across battery pack configurations. The observable parameters demonstrate the system's capability to predict complex battery performance characteristics including remaining battery lifetime, cell-to-cell performance variations under different charge and discharge rates, and degradation patterns at end-of-life.

Phase space analysis supports the disclosed machine learning model integration that utilizes historical battery operational data to enhance prediction accuracy for remaining lifetime and degradation patterns. The observables framework enables real-time simulation of battery degradation processes and facilitates comprehensive performance optimization analysis for electric vehicle and energy storage applications. The mathematical representation validates the disclosed adaptive time stepping capabilities and numerical stability maintenance through implicit integration schemes, demonstrating the robust computational foundation supporting the claimed thermal runaway probability assessment and safety evaluation methodologies across large-scale battery pack configurations.

The disclosed methods may be embodied as a computer program product stored on non-transitory computer-readable storage media including memory devices, optical storage systems, or magnetic storage systems. The computer-readable storage medium stores program instructions that, when executed by one or more processors, implement the computational operations, file processing, matrix generation, and simulation methods disclosed herein. The program code may be written in programming languages suitable for mathematical computation and engineering analysis, including Julia, C++, Java, Python, or C, with specialized libraries for numerical analysis, matrix operations, and differential equation solving.

The disclosed system may incorporate machine learning algorithms, machine learning models, and supervised or unsupervised learning techniques to improve prediction accuracy and performance assessment operations. The machine learning components process training data to develop predictive models that enable enhanced accuracy for performance characteristics and operational predictions beyond purely physics-based calculations.

The disclosed methods may be implemented using various system architectures including client-server configurations, cloud computing infrastructure, software-as-a-service models, or standalone computer systems. The system architecture supports distributed processing across multiple computing devices and enables parallel execution of computational operations. Cloud-based implementations facilitate real-time monitoring and analysis through optimized computational resource allocation and adaptive load balancing across available processing units.

The system integrates file processing capabilities with specialized computational libraries to enable importation of design files and automatic generation of mathematical representations. The computational framework utilizes hardware-optimized mathematical libraries for matrix operations, numerical calculations, and equation solving. Implementation may utilize standard computing hardware including general-purpose processors, specialized processing units, and distributed computing resources as appropriate for the specific operational requirements.

1. A computer-implemented method for modeling thermal and electrochemical properties of lithium-ion battery packs, comprising:
receiving, by a processor, a physics-based thermo-electro-chemical battery model comprising electrochemical reaction equations and thermal transport equations;
importing a computer aided design (CAD) file defining physical cell arrangements within a battery pack;
automatically generating thermal connectivity matrices from the CAD file, wherein the matrices define heat transfer pathways between adjacent cells;
executing a scaling algorithm that transforms single-cell Single-Particle Model (SPM) equations into multi-cell coupled differential equations for the battery pack;
simulating thermal and electrochemical behavior across the battery pack using the scaled equations; and
determining at least one battery performance characteristic based on the simulation.

2. The method of claim 1, wherein the battery performance characteristic comprises at least one of: thermal runaway probability, remaining battery lifetime, cell-to-cell performance variations under different charge/discharge rates, and degradation patterns at end-of-life.

3. The method of claim 1, wherein the physics-based thermo-electro-chemical battery model comprises at least one of: Doyle-Fuller-Newman (DFN) model, Single-Particle Model (SPM), or SPM with electrolyte (SPMe).

4. The method of claim 1, wherein automatically generating thermal connectivity matrices comprises:
extracting three-dimensional cell position coordinates from the CAD file;
calculating inter-cell distances and contact areas;
determining thermal resistance values based on cell casing materials and air gaps; and
constructing a sparse matrix representation of thermal coupling coefficients.

5. The method of claim 1, wherein the scaling algorithm comprises:
decomposing the battery pack into hierarchical thermal zones;
applying model order reduction techniques to repeated cell structures;
implementing algebraic simplification of symbolic expressions; and
generating cell-specific compiled code segments for parallel execution.

6. The method of claim 2, wherein determining thermal runaway probability comprises:
monitoring temperature gradients exceeding 5° C. between adjacent cells;
computing exothermic reaction rates using Arrhenius kinetics when cell temperature exceeds 60° C.;
determining separator melting probability based on material-specific thermal thresholds; and
executing Monte Carlo simulations to assess cascade failure propagation.

7. The method of claim 1, further comprising:
discretizing partial differential equations using finite volume method (FVM);
solving coupled thermo-electrochemical equations with adaptive time stepping; and
maintaining numerical stability through implicit integration schemes.

8. The method of claim 1, wherein the scaling algorithm maintains O(n) computational complexity for battery packs containing up to 10,000 cells, wherein n represents the number of cells.

9. The method of claim 2, further comprising generating a safety assessment report identifying cells with thermal runaway probability exceeding a predetermined threshold.

10. The method of claim 1, wherein the CAD file comprises at least one of: hexagonal module configurations, square module configurations, cylindrical jelly-roll arrangements, prismatic arrangements, or pouch cell arrangements.

11. A non-transitory computer-readable storage medium storing instructions that, when executed by at least one processor, cause a computing system to perform operations for modeling thermal and electrochemical properties of lithium-ion battery packs, the operations comprising:
receiving a physics-based thermo-electro-chemical battery model comprising electrochemical reaction equations and thermal transport equations;
importing a computer aided design (CAD) file defining physical cell arrangements within a battery pack;
automatically generating thermal connectivity matrices from the CAD file, wherein the matrices define heat transfer pathways between adjacent cells;
executing a scaling algorithm that transforms single-cell Single-Particle Model (SPM) equations into multi-cell coupled differential equations for the battery pack;
simulating thermal and electrochemical behavior across the battery pack using the scaled equations; and
determining at least one battery performance characteristic based on the simulation.

12. The storage medium of claim 11, wherein the battery performance characteristic comprises at least one of: thermal runaway probability, remaining battery lifetime, cell-to-cell performance variations under different charge/discharge rates, and degradation patterns at end-of-life.

13. The storage medium of claim 11, wherein the operations further comprise implementing real-time thermal monitoring with update frequencies of at least 10 Hz during high-current discharge events.

14. The storage medium of claim 11, wherein the operations further comprise:
modeling cylindrical cell thermal dynamics using radial heat equation solutions;
accounting for azimuthal and axial temperature variations in cylindrical cells; and
coupling surface-to-core temperature differentials with ambient cooling conditions.

15. The storage medium of claim 11, wherein the operations further comprise generating a safety assessment report that includes:
visual heat maps showing temperature distributions across the battery pack;
identification of thermal hotspots with temperature deviations exceeding 10° C. from pack average;
recommended cooling system modifications to mitigate identified risks; and
time-to-failure estimates for critical thermal scenarios.

16. The storage medium of claim 11, wherein the operations achieve prediction accuracy within 0.5% error for battery state-of-charge and current under standard drive cycles.

17. The storage medium of claim 11, wherein the thermal connectivity matrices incorporate:
conductive heat transfer through cell casings and interconnects;
convective heat transfer coefficients for air or liquid cooling systems;
radiative heat transfer between non-adjacent cells; and
phase change material thermal buffers when present.

18. The storage medium of claim 11, wherein the operations further comprise:
validating simulation results against experimental thermal data;
adjusting model parameters based on cell-to-cell manufacturing variations;
implementing adaptive mesh refinement for regions approaching predetermined thermal conditions; and
dynamically adjusting simulation time steps based on temperature rate-of-change.

19. The storage medium of claim 11, wherein determining battery performance characteristics includes training machine learning models on historical battery operational data to increase prediction accuracy for remaining lifetime and degradation patterns.
